(19) United States
(12) Patent Application Publication
(10) Pub. No.: US 2025/0181108 A1
(43) Pub. Date: Jun. 5, 2025

(54) ELECTRONIC APPARATUS

(71) Applicant: Lenovo (Beijing) Limited, Beijing (CN)

(72) Inventors: Jinshan CHEN, Beijing (CN); Yan LIANG, Beijing (CN)

(21) Appl. No.: 18/924,997

(22) Filed: Oct. 23, 2024

(30) Foreign Application Priority Data
Nov. 30, 2023 (CN) 202311622377.6

(51) Int. Cl. G06F 1/16

(52) U.S. Cl. CPC G06F 1/1601

(57) ABSTRACT

An electronic apparatus includes a monitor; a support structure for supporting the monitor; and a drive component, arranged on a back of the monitor and connected to the support structure. When a relative position relationship between the monitor and the support structure changes, the drive component is configured to change an angle between at least two areas of the monitor and to provide the monitor with at least two different structural forms.

### CROSS-REFERENCE TO RELATED APPLICATION

This application claims priority to Chinese Patent Application No. 202311622377.6, filed on Nov. 30, 2023, the entire content of which is incorporated herein by reference.

### TECHNICAL FIELD

The present disclosure generally relates to the field of computer technology, and, more particularly, to an electronic apparatus.

### BACKGROUND

A monitor of an electronic apparatus can be switched between landscape and portrait to achieve different display modes. The switch between landscape and portrait only changes the display direction and cannot meet the needs of users.

### SUMMARY

One embodiment of the present disclosure provides an electronic apparatus. The electronic apparatus includes a monitor; a support structure for supporting the monitor; and a drive component, arranged on a back of the monitor and connected to the support structure. When a relative position relationship between the monitor and the support structure changes, the drive component is configured to change an angle between at least two areas of the monitor and to provide the monitor with at least two different structural forms.

### BRIEF DESCRIPTION OF THE DRAWINGS

FIG. 1 illustrates a schematic structural diagram of an electronic apparatus consistent with various embodiments of the present disclosure.

FIG. 2 illustrates a schematic structural diagram of another electronic apparatus consistent with various embodiments of the present disclosure.

FIG. 3 illustrates a schematic structural diagram of another electronic apparatus consistent with various embodiments of the present disclosure.

FIG. 4 illustrates a schematic diagram of an exploded structure of an electronic apparatus consistent with various embodiments of the present disclosure.

FIG. 5 illustrates a schematic diagram of a back shell of an electronic apparatus consistent with various embodiments of the present disclosure.

FIG. 6 illustrates a schematic diagram of an exploded structure of another electronic apparatus consistent with various embodiments of the present disclosure.

FIG. 7 illustrates a schematic structural diagram of another electronic apparatus consistent with various embodiments of the present disclosure.

FIG. 8 illustrates a schematic structural diagram of another electronic apparatus consistent with various embodiments of the present disclosure.

FIG. 9 illustrates a schematic diagram of a partial structure of an electronic apparatus consistent with various embodiments of the present disclosure.

FIG. 10 illustrates a schematic structural diagram of a push-pull rod of an electronic apparatus consistent with various embodiments of the present disclosure.

### DETAILED DESCRIPTION OF THE EMBODIMENTS

Specific embodiments of the present disclosure are hereinafter described with reference to the accompanying drawings. The described embodiments are merely examples of the present disclosure, which may be implemented in various ways. Specific structural and functional details described herein are not intended to limit, but merely serve as a basis for the claims and a representative basis for teaching one skilled in the art to variously employ the present disclosure in substantially any suitable detailed structure. Various modifications may be made to the embodiments of the present disclosure. Those skilled in the art will envision other modifications within the scope and spirit of the present disclosure.

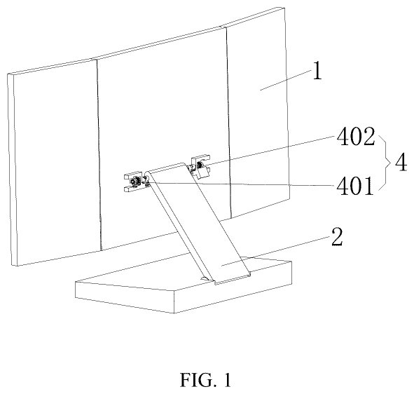

The present disclosure provides an electronic apparatus. As shown in FIG. 1 to FIG. 6, in one embodiment, the electronic apparatus may include a monitor 1, a support structure 2, and a drive component 3. The support structure 2 may be used to support the monitor 1. The electronic apparatus is placed on a carrier surface of a carrier through the support structure 2.

The drive component 3 may be arranged on the back of the monitor 1 and connected to the support structure 2. The drive component 3 may be used to drive the angle between at least two areas of the monitor 1 to change when the relative position relationship between the monitor 1 and the support structure 2 changes, such that the monitor 1 has at least two different structural forms.

The electronic apparatus may be placed on the carrier surface such as a desktop through the support structure 2, and the position relationship of the monitor 1 relative to the support structure 2 may be able to be adjusted. By adjusting the position relationship relative to the support structure 2, the spatial posture or structural form of the monitor 1 may be changed.

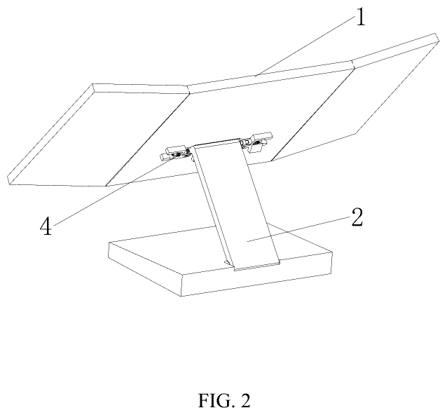

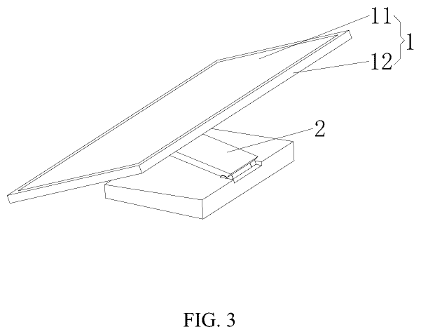

In one embodiment, by adjusting the positional relationship relative to the support structure 2, the spatial posture change of the monitor 1 may include switching between the horizontal screen and the vertical screen. The monitor 1 may rotate relative to the support structure 2, and the spatial posture may be converted from the horizontal screen to the vertical screen, such that the monitor 1 performs display in the vertical screen. Or the monitor 1 may be rotated, and the spatial posture may be converted from the vertical screen to the horizontal screen, such that the monitor 1 performs display in the horizontal screen. By adjusting the positional relationship relative to the support structure 2, the spatial posture change of the monitor 1 may also include a change in the angle between the monitor 1 and the carrier surface. As shown in FIG. 1, the monitor 1 may be substantially perpendicular to the carrier surface, and the monitor 1 may have a curved surface form. Or, as shown in FIG. 2, the angle between the monitor 1 and the carrier surface may be less than 90°, and the curvature of the monitor 1 may be less than the curvature of the monitor 1 shown in FIG. 1. Or, as shown in FIG. 3, the monitor 1 may be substantially parallel to the carrier surface or may be in a smaller angle range, and the monitor 1 may be in a flat form. When the monitor 1 is perpendicular to the carrier surface, it may be applicable to the case where the user views the content displayed on the monitor 1. The content displayed on the monitor 1 may include documents, videos, or pictures. When the angle between the monitor 1 and the carrier surface is less than 90° or 45°, it may be applicable to the case where the operation is performed on the monitor 1. For example, the user may perform operations such as writing or drawing on the monitor 1.

When the relative positional relationship between the monitor 1 and the support structure 2 changes, the angle between at least two areas of the monitor 1 may change, such that the monitor 1 has at least two different structural forms. The angle between the at least two areas of the monitor 1 may change, such that the display surface of the monitor 1 is curved or flat to meet different needs and improve user experience. In one embodiment, when the monitor 1 is perpendicular to the carrier surface, the display surface of the monitor 1 may be a curved surface, which may bring an immersive viewing experience to the user when watching the content displayed on the monitor 1, and the viewing experience may be better. When the monitor 1 is basically parallel to the carrier surface, the display surface of the monitor 1 may be a plane, which may facilitate operations such as drawing.

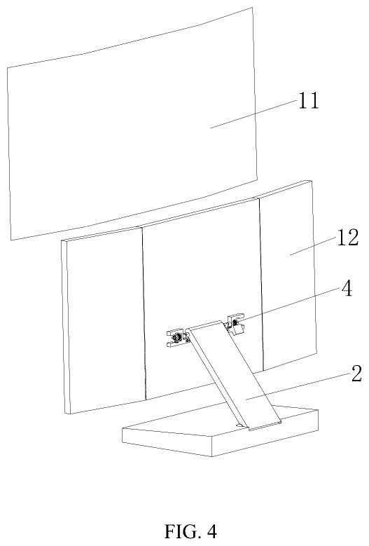

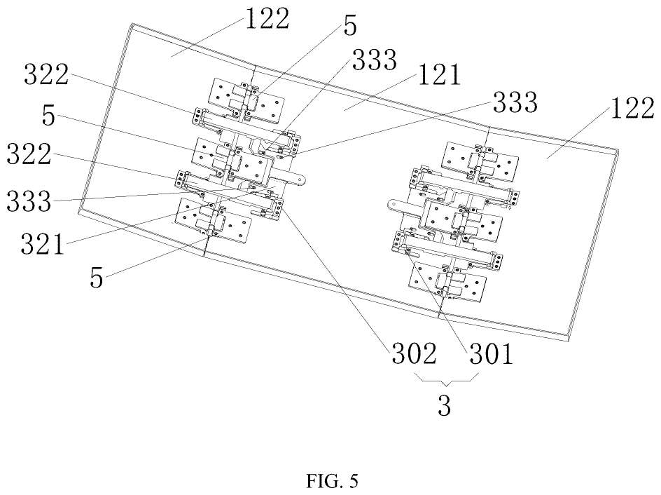

In one embodiment shown in FIG. 3 and FIG. 4, the monitor 1 may include a display panel 11 and a back shell 12 that covers the display panel 11. As shown in FIG. 4 and FIG. 5, the back shell 12 may include a first shell portion 121 and two second shell portions 122 disposed on opposite sides of the first shell portion 121. By rotating the two second shell portions 122 relative to the first shell portion 121, the angle between at least two regions of the display panel 11 may be driven to change, such that the monitor 1 has different structural forms. By rotating the two second shell portions 122 relative to the first shell portion 121, the display panel 11 may be driven to form a curved surface or a flat surface.

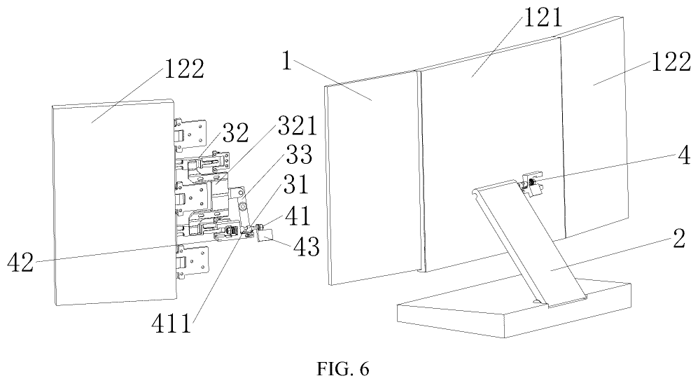

As shown in FIG. 5 and FIG. 6, in one embodiment, the drive component 3 may be disposed on the back shell 12, and the electronic apparatus may further include a rotating shaft structure 4 disposed at the first shell portion 121. The drive component 3 and the support structure 2 may be movably connected through the rotating shaft structure 4. When the relative positional relationship between the monitor 1 and the support structure 2 changes, the rotating shaft structure 4 may drive the drive component 3 to drive the two second shell portions 122 to rotate relative to the first shell portion 121, such that the monitor 1 has different structural forms. The monitor 1 may rotate relative to the support structure 2 through the rotating shaft structure 4, such that the relative position relationship between the two changes. When the monitor 1 rotates relative to the support structure 2 through the rotating shaft structure 4, the rotating shaft structure 4 may drive the drive component 3, such that the drive component 3 drives the two second shell portions 122 to rotate relative to the first shell portion 121. The display panel 11 provided on the back shell 12 may be bent or flattened with the rotation of the two second shell portions 122, such that the monitor 1 has different structural forms. For example, in the horizontal screen state, the monitor 1 may rotate relative to the support structure 2 through the rotating shaft structure 4, such that the monitor 1 is perpendicular to the carrier surface, the display panel 11 of the monitor 1 has a curved surface, and the user has an immersive viewing experience. Or, in the horizontal screen state, the monitor 1 may rotate relative to the support structure 2 through the rotating shaft structure 4, such that the monitor 1 is basically parallel to the carrier surface, the display panel 11 of the monitor 1 is a plane, and the user is able to perform operations such as drawing or file processing.

The drive component 3 may be arranged near the edge of the back shell 12. In one embodiment, the drive component 3 may be arranged at one-fifth of the back shell 12, and the distance between the drive component 3 and the edge of the back shell 12 is one-fifth of the overall length of the back shell 12.

As shown in FIG. 5 and FIG. 6, the drive component 3 may be arranged on the side of the back shell 12 facing the display panel 11. The rotating shaft structure 4 may be arranged on the same side as the drive component 3, and the rotating shaft structure 4 may pass through the first shell portion 121 to connect with the support structure 2. In some other embodiments, the rotating shaft structure 4 may also be arranged on a different side of the back shell 12 from the drive component 3, and the drive component 3 may pass through the first shell portion 121 to connect with the rotating shaft structure 4.

The drive component 3 may be arranged between the first shell portion 121 and the two second shell portions 122. Driven by the shaft, the drive component 3 may drive the two second shell portions 122 to rotate relative to the first shell portion 121, thereby driving the display panel 11 to bend into a curved surface or flatten into a plane.

The drive component 3 may also be disposed on a side of the back shell 12 facing away from the display panel 11. The rotating shaft structure 4 may be disposed on a side of the first shell portion 121 facing away from the display surface, and the rotating shaft structure 4 may be connected to the support structure 2.

In one embodiment, as shown in FIG. 1 to FIG. 3, the monitor 1 shown in FIG. 1 may have the largest curvature, the monitor 1 shown in FIG. 3 may be in a planar state, and the monitor 1 shown in FIG. 2 may be in an intermediate form in which FIG. 1 and FIG. 3 are switched. In different structural forms, the curvature of the monitor 1 may be different. The display panel 11 may be bent or flattened under the drive of the two second shell portions 122, and may present different curvatures.

As shown in FIG. 3, when the display panel 11 is flattened into a plane, the curvature may be 0. For example, the electronic apparatus may be placed on the carrier surface through the support structure 2, and the monitor 1 in the horizontal screen state may be rotated relative to the support structure 2 in a direction parallel to the carrier surface through the rotating shaft structure 4. Therefore, the display panel 11 may be flattened to a plane with a curvature of 0. When the display panel 11 is a plane, the angle between the display panel 11 and the carrier surface may be 0° or an appropriate acute angle to facilitate user operation. For example, when the display panel 11 is a plane, the angle between the display panel 11 and the carrier surface may be 0° to 60°, such as 45°, 30°, 15°, etc.

The electronic apparatus may be placed on a carrier surface through the support structure 2, and the monitor 1 in a horizontal screen state may be rotated relative to the support structure 2 in a direction tending to be perpendicular to the carrier surface via the rotating shaft structure 4. The display panel 11 may be gradually bent from a plane, and the curvature may gradually increase. When the display panel 11 is perpendicular to the carrier surface, the curvature of the display panel 11 may be the largest.

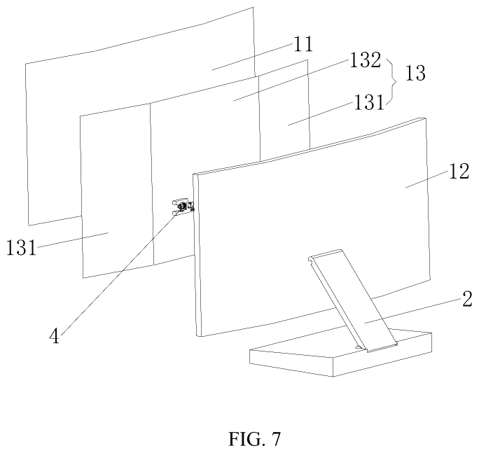

In another embodiment shown in FIG. 7, the monitor 1 may include a display panel 11, a back shell 12 covering the display panel 11, and a back plate 13 disposed on the back of the display panel 11 for supporting the display panel 11. The back plate 13 may include a second plate 132 and two first plates 131 disposed on opposite sides of the second plate 132. The two first plates 131 may be able to rotate relative to the second plate 132, thereby driving the angle between at least two regions of the display panel 11 to change, such that the monitor 1 has different structural forms such as a plane form and a curved form. The display panel 11 may be bent into a curved surface or flattened into a plane by rotating the two first plates 131 relative to the second plate 132. The back of the display panel 11 may be supported by the back plate 13, and the display panel 11 may be driven to be bent or flattened by the back plate 13 while the shape of the back shell 12 may remain unchanged, such that the display panel 11 is bent or flattened in the back shell 12 to display in different structural forms.

The drive component 3 may be arranged on the back plate 13, and the electronic apparatus may further include a rotating shaft structure 4 arranged on the back plate 13. The drive component 3 and the support structure 2 may be movably connected through the rotating shaft structure 4. The rotating shaft structure 4 may be arranged on the second plate 132.

The drive component 3 may be arranged near the edge of the back plate 13. In one embodiment, the drive component 3 may be arranged at one-fifth of the back plate 13, and the distance between the drive component 3 and the edge of the back plate 13 may be one-fifth of the overall length of the back plate 13.

The drive component 3 may also be arranged on the side of the back plate 13 facing the screen, and the rotating shaft structure 4 may be arranged on the same side as the drive component 3. The rotating shaft structure 4 passes through the first shell portion 121 to connect with the support structure 2. The rotating shaft structure 4 may also be arranged on a side of the back shell 12 different from the drive component 3, and the drive component 3 may pass through the first shell portion 121 to connect with the rotating shaft structure 4.

The drive component 3 may also be arranged on the side of the back plate 13 facing away from the display panel 11, and the rotating shaft structure 4 may be arranged on the side of the back plate 13 facing away from the display surface. The rotating shaft structure 4 may be connected with the support structure 2.

The drive component 3 may be disposed between the second plate 132 and the two first plates 131. Driven by the shaft, the drive component 3 may drive the two first plates 131 to rotate relative to the second plate 132, thereby driving the display panel 11 to bend into a curved surface or flatten into a plane.

In different structural forms, the curvature of the monitor 1 may be different. The display panel 11 may be bent or flattened under the drive of the two first plate 131, and may present different curvatures including a planar state and curved states with different curvatures.

When the display panel 11 is flattened into a plane, the curvature may be 0. For example, the electronic apparatus may be placed on the carrier surface through the support structure 2, and the monitor 1 in the horizontal screen state may be rotated relative to the support structure 2 through the rotating shaft structure 4. The angle between the display panel 11 and the carrier surface may gradually decrease. The display panel 11 may be flattened to a plane driven by the two first back plates 13. Therefore, the display panel 11 may be flattened to a plane with a curvature of 0. When the display panel 11 is a plane, the angle between the display panel 11 and the carrier surface may be 0° or an appropriate acute angle to facilitate user operation. For example, when the display panel 11 is a plane, the angle between the display panel 11 and the carrier surface may be 0° to 60°, such as 45°, 30°, 15°, etc.

The electronic apparatus may be placed on a carrier surface through the support structure 2, and the monitor 1 in a horizontal screen state may be rotated relative to the support structure 2 through the rotating shaft structure 4. The angle between the display panel 11 and the carrier surface may gradually increase. The display panel may be bent gradually driven by the two first plates 131, and the curvature may gradually increase. When the display panel 11 is perpendicular to the carrier surface, the curvature of the display panel 11 may be the largest.

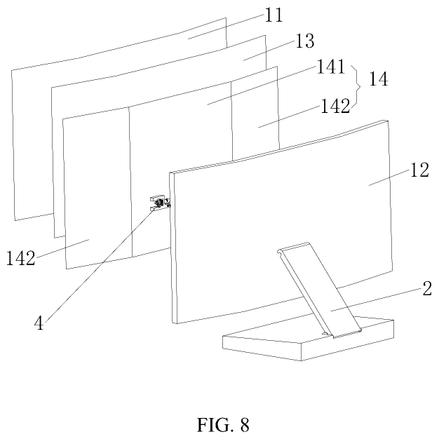

In another embodiment shown in FIG. 8, the monitor 1 may include a display panel 11, a back shell 12 covering the display panel 11, and a back plate 13 disposed on the back of the display panel 11 for supporting the display panel 11. The back plate 13 may be a plate with certain elasticity such as a steel plate. The display panel 11 may be a flexible display panel 11. The back plate 13 may support the display panel 11 and may be bent or flattened along with the display panel 11.

As shown in FIG. 8, the electronic apparatus may further include a plate structure 14 disposed between the back plate 13 and the back shell 12. The plate structure 14 may include a third plate 141 and two fourth plates 142 disposed on opposite sides of the third plate 141. The drive component 3 may be disposed on the plate structure 14. The two opposite edges of the plate structure 14 may be connected to the back plate 13. The two fourth plates 142 may rotate relative to the third plate 141, thereby driving the angle between at least two regions of the display panel 11 to change, such that the monitor 1 has different structural forms such as a plane form or a curved form. The display panel 11 may be bent into a curved surface or flattened into a plane by rotating the two fourth plates 142 relative to the third plate 141. The display panel 11 may be driven by the back plate 13 to be bent into a curved surface or flattened into a plane, and the shape of the back shell 12 may remain unchanged, such that the display panel 11 is bent or flattened in the back shell 12 to display in different structural forms.

The drive component 3 may be arranged near the edge of the plate structure 14. In one embodiment, the drive component 3 may be arranged at one-fifth of the plate structure 14, and the distance between the drive component 3 and the edge of the plate structure 14 may be one-fifth of the overall length of the plate structure 14.

The rotating shaft structure 4 may be arranged on the third plate 141, and the drive component 3 and the support structure 2 may be movably connected through the rotating shaft structure 4. When the relative position relationship between the monitor 1 and the support structure 2 changes, the rotating shaft structure 4 may drive the drive component 3 to drive the two fourth plates 142 to rotate relative to the third plate 141, such that the the back plate 13 is driven to deform and the monitor 1 has a different structural form. For example, in the horizontal screen state, the monitor 1 may rotate relative to the support structure 2 through the rotating shaft structure 4, such that the angle between the monitor 1 and the carrier surface gradually increases and the display panel 11 gradually bends from a flat surface to a curved surface. Therefore, the user may have an immersive viewing experience. Or, in the horizontal screen state, the monitor 1 may rotate relative to the support structure 2 through the rotating shaft structure 4, such that the angle between the display panel 11 and the carrier surface gradually decreases, and the display panel 11 gradually flattens from a curved surface to a flat surface. The user may perform operations such as painting and file processing. When the display panel 11 is a curved surface, it may be basically perpendicular to the carrier surface for user viewing. When the display panel 11 is a curved surface, the angle between it and the carrier surface may be an acute angle or basically parallel to the carrier surface, such that the user may perform operations such as painting or file processing.

In different structural forms, the curvature of the monitor 1 may be different. The display panel 11 may be bent or flattened under the drive of the two first plate 131, and may present different curvatures including a planar state and curved states with different curvatures.

The monitor 1 may rotate relative to the support structure 2 through the rotating shaft structure 4, such that the relative position relationship between the two changes. When the monitor 1 rotates relative to the support structure 2 through the rotating shaft structure 4, the rotating shaft structure 4 may drive the drive component 3, such that the drive component 3 drives the two fourth plates 142 to rotate relative to the third plate 141. The display panel 11 is bent or flattened with the rotation of the two fourth plates 142, such that the monitor 1 has a different structural form. For example, the electronic apparatus may be placed on the carrier surface through the support structure 2, and the monitor 1 in the horizontal screen state may be rotated relative to the support structure 2 through the rotating shaft structure 4. The angle between the display panel 11 and the carrier surface may gradually decrease. The display panel 11 may be flattened to a plane driven by the two first back plates 13. Therefore, the display panel 11 may be flattened to a plane with a curvature of 0. When the display panel 11 is a plane, the angle between the display panel 11 and the carrier surface may be 0° or an appropriate acute angle to facilitate user operation. For example, when the display panel 11 is a plane, the angle between the display panel 11 and the carrier surface may be 0° to 60°, such as 45°, 30°, 15°, etc.

The electronic apparatus may be placed on a carrier surface through the support structure 2, and the monitor 1 in a horizontal screen state may be rotated relative to the support structure 2 through the rotating shaft structure 4. The angle between the display panel 11 and the carrier surface may gradually increase. The display panel may be bent gradually driven by the two first plates 131, and the curvature may gradually increase. When the display panel 11 is perpendicular to the carrier surface, the curvature of the display panel 11 may be the largest.

In one embodiment shown in FIG. 6, the rotating shaft structure 4 may include a first shaft 41, a shaft seat 42 and a first rotating member 43. The shaft seat 42 may be used to support the first shaft 41 to rotate. The shaft seat 42 may be used alone or in a pair, such that the two ends of the first shaft 41 are respectively rotatably arranged on one shaft seat 42.

As shown in FIG. 6, the shaft seat 42 may be arranged on the back shell 12. In one embodiment, the shaft seat 42 may be arranged on the side of the first shell portion 121 facing away from the display panel 11, to facilitate the connection between the rotating shaft structure 4 and the support structure 2. The drive component 3 may be arranged on the side of the back shell 12 facing the display panel 11, and the drive component 3 may pass through the back shell 12 to connect with the rotating shaft structure 4.

In another embodiment shown in FIG. 7, the shaft seat 42 may also be arranged on the side of the back plate 13 facing away from the display panel 11. For example, the shaft seat 42 may be arranged on the side of the second plate 132 facing away from the display panel 11, and the support structure 2 may pass through the back shell 12 to connect with the rotating shaft structure 4. The drive component 3 may be arranged on the side of the back plate 13 facing the display panel 11, and the drive component 3 may be connected to the rotating shaft structure 4 through the back plate 13.

In another embodiment shown in FIG. 8, the shaft seat 42 may be arranged on the side of the plate structure 14 away from the display panel 11. For example, the shaft seat 42 may be arranged on the side of the third plate 141 facing away from the display panel 11, to facilitate the connection between the rotating shaft structure 4 and the support structure 2. The drive component 3 may be arranged on the side of the plate structure 14 facing the display panel 11, and the support structure 2 may be connected to the rotating shaft structure 4 through the back shell 12. The drive component 3 may be connected to the rotating shaft structure 4 through the plate structure 14.

The first rotating member 43 may be sleeved on the first rotating shaft 41. The first rotating member 43 may be fixedly connected to the support structure 2 and may be movably connected to the drive component 3. When the support structure 2 rotates relative to the monitor 1, the first rotating member 43 or the driving portion 411 arranged on the first rotating shaft 41 may apply a force to the drive component 3, such that the drive component 3 drives the back panel 13 or the back shell 12 of the monitor 1 to deform. Therefore, the monitor 1 may have at least a curved shape and a flat shape.

When the support structure 2 rotates relative to the monitor 1 through the rotating shaft structure 4, one of the first rotating member 43 and the driving portion 411 on the first rotating shaft 41 may apply a force to the drive component 3, such that the drive component 3 drives the back plate 13, the back shell 12 or the plate structure 14 to deform, to make the monitor 1 be a curved surface, and the other one may apply a force to the drive component 3, such that the drive component 3 drives the back plate 13, the back shell 12 or the plate structure 14 to deform, to make the monitor 1 have a flat surface.

In one embodiment, in the horizontal screen state, when the monitor 1 rotates relative to the support structure 2 such that the angle between the display panel 11 and the carrier surface decreases, the first rotating member 43 may apply a force to the drive component 3, such that the monitor 1 has a flat surface. When the monitor 1 rotates relative to the support structure 2 such that the angle between the display panel 11 and the carrier surface increases, the driving portion 411 may apply a force to the drive component 3, such that the monitor 1 has a curved surface.

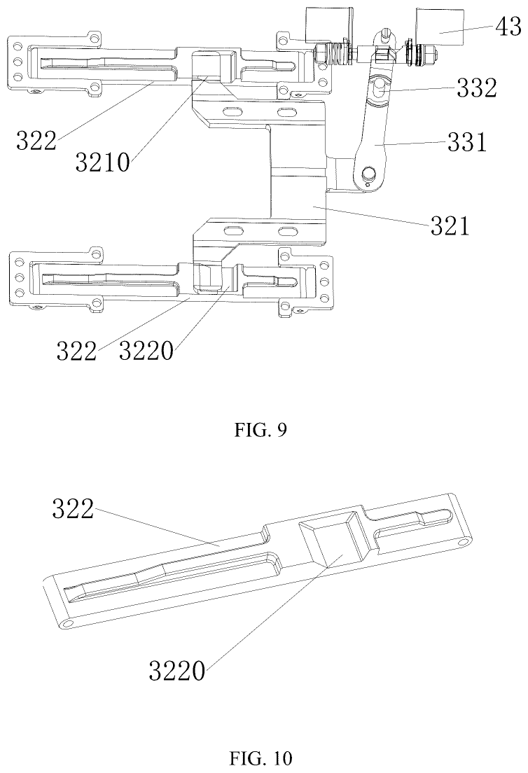

In one embodiment, as shown in FIG. 6 and FIG. 9, the drive component 3 may include a second rotating member 31, a push-pull component 32 and a transmission component 33. The second rotating member 31 may be sleeved on the first rotating shaft 41. The second rotating member 31 may be movably connected with the first rotating member 43 or the driving portion 411 disposed on the first rotating shaft 41, and may move in the axial direction of the first rotating shaft 41 under the action of the first rotating member 43.

The second rotating member 31 may be disposed between the driving portion 411 and the first rotating member 43. Under the action of the driving portion 411, the second rotating member 31 may move in a direction away from the driving portion 411. Under the action of the first rotating member 43, the second rotating member 31 may move in a direction away from the first rotating member 43.

In one embodiment, the first rotating member 43 may include a first cam structure in contact with the second rotating member 31. When the monitor 1 rotates relative to the support structure 2 via the rotating shaft structure 4, the second rotating member 31 and the first rotating member 43 may rotate relative to each other. Under the action of the first cam structure, the second rotating member 31 may move along the shaft of the first rotating shaft 41 in a direction away from the first rotating member 43.

The driving portion 411 may also include a second cam structure. When the monitor 1 rotates relative to the support structure 2 via the rotating shaft structure 4, the second rotating member 31 and the driving portion 411 may rotate relative to each other. The second cam structure may contact the second rotating member 31. Under the action of the second cam structure, the second rotating member 31 may move along the shaft of the first rotating shaft 41 in a direction away from the driving portion 411.

A spring may also be sleeved on the first rotating shaft 41, and the second rotating member 31 may be located between the spring and the first rotating member 43. Under the action of the spring, the second rotating member 31 may move along the shaft of the first rotating shaft 41 in a direction away from the spring.

The push-pull component 32 may be movably arranged on the back shell 12, the back plate 13 or the plate structure 14 of the monitor 1. The push-pull component 32 may apply a push or pull force to the movable part of the back shell 12, the back plate 13 or the plate structure 14, such that the back shell 12, the back plate 13 or the plate structure 14 is deformed.

When the push-pull component 32 is arranged on the side of the back shell 12, the back plate 13 or the plate structure 14 facing the display panel 11, the push-pull component 32 may apply a pull force to the movable part of the back shell 12, the back plate 13 or the plate structure 14, such that the back shell 12, the back plate 13 or the plate structure 14 is deformed, thereby driving the display panel 11 to form a concave curved surface. Therefore, the user may have an immersive viewing experience.

When the push-pull component 32 is arranged on the side of the back shell 12, the back plate 13 or the plate structure 14 facing away from the display panel 11, the push-pull component 32 may apply a push force to the movable part of the back shell 12, the back plate 13 or the plate structure 14, such that the back shell 12, the back plate 13 or the plate structure 14 is deformed, thereby driving the display panel 11 to form a concave curved surface.

The push-pull component 32 may be arranged on the side of the back shell 12 facing the display panel 11. The first shell portion 121 may be the main part of the back shell 12 and may be considered as a relatively fixed part. The two second shell portions 122 may be movable parts of the back shell 12. The push-pull component 32 may be respectively connected to the first shell portion 121 and the second shell portions 122. The push-pull component 32 may apply a pulling force to the second shell portions 122, to make the second shell portions 122 rotate relative to the first shell portion 121, such that the back shell 12 is deformed to drive the display panel 11 to bend into a curved surface.

In another embodiment, the push-pull component 32 may be arranged on the side of the back plate 13 facing the display panel 11. The second plate 132 may be the main part of the back plate 13 and may be considered as a relatively fixed part. The two first plates 131 may be movable parts of the back plate 13. The push-pull component 32 may be respectively connected to the second plate 132 and the first plates 131. The push-pull component 32 may apply a pulling force to the first plates 131. The two first plates 131 may rotate relative to the second plate 132, so that the back plate 13 is deformed to drive the display panel 11 to bend into a curved surface.

In another embodiment, the push-pull component 32 may be arranged on the side of the plate structure 14 facing the display panel 11. The third plate 141 may be the main part of the plate structure 14 and may be considered as a relatively fixed part of the plate structure. The two fourth plates 142 may be movable parts of the plate structure 14. The push-pull component 32 may be respectively connected to the third plate 141 and the fourth plates 142. The push-pull component 32 may apply a pulling force to the fourth plates 142. The two fourth plates 142 may rotate relative to the third plate 141, to make the plate structure 14 deform, thereby driving the display panel 11 to bend into a curved surface.

The transmission component 33 may connect the second rotating member 31 and the push-pull component 32. The transmission component 33 may be used to transmit a force to the push-pull component 32 when the second rotating member 31 moves, to drive the push-pull component 32 to move. When the second rotating member 31 moves along the axis of the first rotating shaft 41, the transmission component 33 may transmit a force to the push-pull component 32, to drive the push-pull component 32 to move and to change the structural form of the monitor 1.

In one embodiment, as shown in FIG. 9, the transmission component 33 may include a connecting rod 331 and a second rotating shaft 332 disposed on the first shell portion 121 of the back shell 12, the second plate 132 of the back plate 13, or the third plate 141 of the plate structure 14. The connecting rod 331 may rotate through the second rotating shaft 332. Two opposite ends of the connecting rod 331 may be respectively connected to the second rotating member 31 and the push-pull component 32.

In one embodiment, when the second rotating member 31 moves in the first direction, the connecting rod 331 may rotate in the third direction, for example, the connecting rod 331 may rotate counterclockwise and drive the push-pull component 32 to apply a push force to the movable part of the back shell 12, the back plate 13 or the plate structure 14.

In one embodiment, when the second rotating member 31 moves in the second direction, the connecting rod 331 may rotate in the fourth direction, for example, the connecting rod 331 may rotate clockwise and drive the push-pull component 32 to apply a pulling force to the movable part of the back shell 12, the back plate 13 or the plate structure 14.

The first direction may be opposite to the second direction. In one embodiment, the first rotating shaft 41 may be disposed on the main body of the back shell 12, the back plate 13 or the plate structure 14, such as the first shell portion 121, the second plate 132 or the third plate 141. The first direction may be a direction away from the movable part of the back shell 12, the back plate 13 or the plate structure 14, and the second direction may be a direction close to the movable part of the back shell 12, the back plate 13 or the plate structure 14.

In one embodiment, as shown in FIG. 9, the push-pull component 32 may include a transmission member 321 and a push-pull rod 322. The transmission member 321 may be connected to the connecting rod 331. The transmission member 321 may move in the first direction or the second direction under the drive of the connecting rod 331.

One end of the connecting rod 331 may be connected to the second rotating member 31 through a pin shaft, and the other end may be connected to the transmission member 321 through a pin shaft. When the second rotating member 31 moves in the first direction or the second direction, the connecting rod 331 may rotate, thereby driving the transmission member 321 to move. The moving direction of the transmission member 321 may be opposite to the moving direction of the second rotating member 31.

The connecting rod 331 may also be fixedly connected to the second rotating member 31 and the transmission member 321 respectively. When the second rotating member 31 moves in the first direction or the second direction, it may drive the transmission member 321 to move synchronously.

The push-pull component 32 may be arranged on the side of the back shell 12, the back plate 13 or the plate structure 14 facing the display panel 11, and the rotating shaft structure 4 may be arranged on the side of the back shell 12, the back plate 13 or the plate structure 14 facing away from the display panel 11. The back shell 12, the back plate 13 or the plate structure 14 may be provided with holes or grooves correspondingly, such that the connecting rod 331 passes through the back shell 12, the back plate 13 or the plate structure 14 through the holes or grooves to connect the push-pull component 32 and the second rotating member 31.

The transmission member 321 may be arranged on the main part of the back shell 12, the back plate 13 or the plate structure 14, such as the first shell portion 121, the second plate 132 or the third plate 141, and the transmission member 321 may be slidably connected with the first shell portion 121, the second plate 132 or the third plate 141. For example, the first shell portion 121, the second plate 132 or the third plate 141 may have a slide groove, and the transmission member 321 may slide along the slide groove. Alternatively, in another example, the transmission member 321 may have a guide groove, and the first shell portion 121, the second plate 132 or the third plate 141 may have a guide column that cooperates with the guide groove. When the transmission member 321 slides relative to the first shell portion 121, the second plate 132 or the third plate 141, the guide column may slide relatively in the guide groove.

Two opposite ends of the push-pull rod 322 may be rotatably connected to the movable part and the main part of the back shell 12, the back plate 13 or the plate structure 14, respectively. As shown in FIG. 9 and FIG. 10, the push-pull rod 322 may include at least one connecting groove 3220, and part of the bottom wall of the at least one connecting groove 3220 may have a slope.

The movable part of the back shell 12, the back plate 13 or the plate structure 14 may be respectively the second shell portion 122, the first plate 131 or the fourth plate 142, and the main part of the back shell 12, the back plate 13 or the plate structure 14 may be a fixed part relative to the movable part, respectively the first shell portion 121, the second plate 132 or the third plate 141.

The first end 3210 of the transmission member 321 away from the connecting rod 331 may be movably arranged in the connecting groove 3220.

When the second rotating member 31 moves in the first direction, the connecting rod 331 may drive the transmission member 321 to move in the second direction, such that the first end 3210 of the transmission member 321 slides to the slope to apply a push force to the movable part of the back shell 12 or the back plate 13 through the slope. When the connecting rod 331 rotates between the second rotating member 31 and the transmission member 321, the movement direction of the transmission member 321 may be opposite to that of the second rotating member 31. When the first end 3210 of the transmission member 321 acts on the slope, the push force may be applied to the push-pull rod 322, and the push-pull rod 322 may drive the movable part of the back shell 12, the back plate 13 or the plate structure 14 to rotate relative to the main body to bend into a curved surface.

When the second rotating member 31 moves in the second direction, the connecting rod 331 may drive the transmission member 321 to move in the first direction, such that the first end 3210 of the transmission member 321 slides out of the slope to apply a pulling force to the movable part of the back shell 12 or the back plate 13.

When the connecting rod 331 rotates to transmit between the second rotating member 31 and the transmission member 321, the transmission member 321 may move in a direction opposite to the second rotating member 31. When the first end 3210 of the transmission member 321 slides out of the slope, a pulling force may be applied to the movable part of the back shell 12 or the back plate 13, such that the movable part of the back shell 12, the back plate 13 or the plate structure 14 rotates relative to the main body to be flattened into a plane.

In one embodiment, a reset spring may be provided between the movable part and the main part of the back shell 12, the back plate 13 or the plate structure 14, and the reset spring may be used to apply a reset force to the movable part. Under the action of the reset force, the movable part may rotate relative to the main part to be flattened. The reset spring may be a torsion spring, and the movable part may be rotatably connected to the main part through a pin shaft. The torsion spring may be sleeved on the pin shaft. One end of the torsion spring may act on the movable part, and the other end may act on the main part to apply a reset force to the movable part. When the first end 3210 of the transmission member 321 slides out of the slope, the push force acting on the push-pull rod 322 may disappear, such that the movable part is able to rotate to be flush with the main part.

In one embodiment, as shown in FIG. 5, the transmission component 33 may include a connecting rod 331, a transmission member 321, a second rotating shaft 332, and at least two third rotating shafts 333 arranged on the first housing portion 121 of the back shell 12, the second plate 132 of the back plate 13, or the third plate 141 of the plate structure 14. The connecting rod 331 may rotate through the second rotating shaft 332, and the transmission member 321 may slide through the at least two third rotating shafts 333. The transmission member 321 may have a guide groove matched with the at least two third rotating shafts 333, such that the transmission member 321 slides in the first direction or the second direction relative to the first housing portion 121 of the back shell 12, the second plate 132 of the back plate 13, or the third plate 141 of the plate structure 14.

Two opposite ends of the connecting rod 331 may be respectively connected to the second rotating member 31 and the transmission member 321. The two ends of the connecting rod 331 may be rotatably connected to the second rotating member 31 and the transmission member 321, respectively. When the second rotating member 31 moves, the rotation of the connecting rod 331 may drive the transmission member 321 to move in the direction opposite to the moving direction of the second rotating member 31.

When the second rotating member 31 moves in the first direction, the connecting rod 331 may rotate in the third direction, for example, may rotate counterclockwise and drive the transmission member 321 to slide in the second direction, to drive the push-pull component 32 to move in the fifth direction and apply a push force to the movable part of the back shell 12 or the back plate 13.

When the second rotating member 31 moves in the second direction, the connecting rod 331 may rotate in the fourth direction, for example, may rotate clockwise and drive the transmission member 321 to slide in the first direction, to drive the push-pull component 32 to move in the sixth direction and apply a pulling force to the movable part of the back shell 12 or the back plate 13.

The first direction may be opposite to the second direction, and the fifth direction may be opposite to the sixth direction.

In one embodiment, as shown in FIG. 5, at least one rotating connector 5 may be further provided between the movable part and the main part of the back shell 12, the back plate 13 or the plate structure 14 to support the relative rotation between the movable part and the main part. The movable part of the back shell 12 may be the second shell portion 122, and the main part may be the first shell portion 121. The movable part of the back plate 13 may be the first plate 131, and the main part may be the second plate 132. The movable part of the plate structure 14 may be the fourth plate 142, and the main part may be the third plate 141.

In one embodiment, one rotating connector 5 may be a hinge, and the movable part and the main part of the back shell 12, the back plate 13 or the plate structure 14 may be connected by the hinge, such that the movable part may rotate relative to the main part.

In another embodiment, the rotating connector 5 may also be a pin, and the movable part and the main part of the back shell 12, the back plate 13 or the plate structure 14 have overlapping hinged parts, and the hinged parts may be connected by the pin, such that the movable part may rotate relative to the main part.

A reset spring may be arranged between the movable part and the main part of the back shell 12, the back plate 13 or the plate structure 14 to provide a reset force to the movable part, such that when the force of the transmission member 321 acting on the push-pull component 32 disappears, the reset force causes the movable part to rotate in the opposite direction to be flush with the main part to make that the display panel 11 flat.

In one embodiment, as shown in FIG. 5 and FIG. 9, two first ends 3210 may be spaced apart on one side of the transmission member 321 away from the connecting rod 331, and the two first ends 3210 may be respectively movably connected to one push-pull rod 322. The transmission member 321 may be simultaneously connected to the two push-pull rods 322, and when the transmission member 321 moves toward the movable part, the two first ends 3210 may slide to the slope of the corresponding push-pull rod 322 respectively, such that the two push-pull rods 322 exert force on the movable part to make the movable part rotate smoothly relative to the main part and drive the display panel 11 to bend into a curved surface.

In one embodiment, as shown in FIG. 1, the rotating shaft structure 4 may include a first rotating shaft structure 401 and a second rotating shaft structure 402. As shown in FIG. 5, the drive component 3 may include a first drive component 301 and a second drive component 302. The first rotating shaft structure 401 and the first drive component 301 may be arranged in a first area of the back shell 12, the back plate 13 or the plate structure 14 of the monitor 1, and the second rotating shaft structure 402 and the second drive component 302 may be arranged in a second area of the back shell 12, the back plate 13 or the plate structure 14. The first area and the second area may be symmetrically arranged on two sides of the center line of the back shell 12, the back plate 13 or the plate structure 14. The first rotating shaft structure 401 and the first drive component 301 may be used to drive one of the movable parts of the back shell 12, the back plate 13 or the plate structure 14 to rotate relative to the main body, and the second rotating shaft structure 402 and the second drive component 302 may be used to drive another movable part of the back shell 12, the back plate 13 or the plate structure 14 to rotate relative to the main body. The structures of the first rotating shaft structure 401 and the second rotating shaft structure 402 may refer to the description of the rotating shaft structure 4 in the above embodiment, and the structure of the first drive component 301 and the second drive component 302 may refer to the description of the drive component 3 in the above embodiment, which will not be described one by one here.

In one embodiment, the first rotating shaft structure 401 and the second rotating shaft structure 402 may be arranged on the first housing portion 121, and the first rotating shaft structure 401 and the second rotating shaft structure 402 may be respectively arranged close to the side of the second housing portion 122 driven by each of them. The first drive component 301 may be connected to the first rotating shaft structure 401 in a transmission manner to drive one of the second housing portions 122 to rotate relative to the first housing portion 121 under the drive of the first rotating shaft structure 401, and the second drive component 302 may be connected to the second rotating shaft structure 402 in a transmission manner to drive the other second housing portion 122 to rotate relative to the first housing portion 121 under the drive of the second rotating shaft structure 402.

In another embodiment, the first rotating shaft structure 401 and the second rotating shaft structure 402 may be arranged on the second plate 132, and the first rotating shaft structure 401 and the second rotating shaft structure 402 may be respectively arranged close to the side of the first plate 131 driven by each of them. The first drive component 301 may be in transmission connection with the first rotating shaft structure 401, to drive one of the first plates 131 to rotate relative to the second plate 132 under the drive of the first rotating shaft structure 401, and the second drive component 302 may be in transmission connection with the second rotating shaft structure 402, to drive another first plate 131 to rotate relative to the second plate 132 under the drive of the second rotating shaft structure 402.

In another embodiment, the first rotating shaft structure 401 and the second rotating shaft structure 402 may be arranged on the third plate 141, and the first rotating shaft structure 401 and the second rotating shaft structure 402 may be respectively arranged close to one side of the fourth plate 142 driven by each. The first drive component 301 may be in transmission connection with the first rotating shaft structure 401, to drive one of the fourth plates 141 to rotate relative to the third plate 141 under the drive of the first rotating shaft structure 401, and the second drive component 302 may be in transmission connection with the second rotating shaft structure 402, to drive another fourth plate 142 to rotate relative to the third plate 141 under the drive of the second rotating shaft structure 402.

In one embodiment, a fiber layer may be further provided on the back side of the back shell 12 facing away from the display panel 11. The fiber layer may protect the back shell 12. In one exemplary embodiment, the fiber layer may be a carbon fiber layer.

In one embodiment, the monitor 1 may further include a backlight control panel for controlling display parameters of the display panel 11. The backlight control panel may be disposed in the main body of the back shell 12 or the back plate 13 of the monitor 1.

In one embodiment, the monitor 1 may further include a touch control panel for controlling touch parameters of the display panel 11. The touch control panel may be disposed in the support structure 2.

The touch control panel may control the touch function of the display panel 11 to be turned on in all structural forms. The touch control panel may also control the touch function of the display panel 11 to be turned on in some structural forms and turned off in some structural forms. In one exemplary embodiment, in a first structural form, the touch control panel may control the touch function of the display panel 11 to be turned off, and in a second structural form, the touch control panel may control the touch function of the display panel 11 to be turned on.

The touch control panel may control the display panel 11 to turn on the touch function in a specified area, which is a touch area. In one exemplary embodiment, the touch control panel may control the touch area to be located in the lower area of the display panel 11. A virtual keyplate may be displayed in the touch area to perform touch input through the virtual keyplate.

In one embodiment, the monitor 1 may further include a posture sensor, which is used to detect the structural posture of the monitor 1. The touch control panel may control the touch parameters of the display panel 11 according to the detection result of the posture sensor.

In one embodiment, when the posture sensor detects that the monitor 1 may be in the third structural form, the touch control panel may control the lower area of the display panel 11 to turn on the touch function to form a touch area at the lower part of the display panel 11. In the third structural form, the display panel 11 may be a curved surface and may be in a vertical screen form. The lower part of the display panel 11 may be a touch area, and the upper part may be a display area. The touch area may have a virtual keyplate to input by operating the virtual keyplate, and the upper area may be used to display data. In the third structural form, the monitor 1 may be used as a laptop.

In one embodiment, when the angle between the monitor 1 and the support structure 2 is in a first angle range, the monitor 1 may be in the first structural form. In one exemplary embodiment, the first angle range may be larger than or equal to 160°. The first structural form may be a curved surface form. When the monitor 1 is basically vertically set, the curvature of the display panel 11 may be the largest, which may provide an immersive viewing experience for the user.

When the angle between the monitor 1 and the support structure 2 is in a second angle range, the monitor 1 may be in the second structural form. In one exemplary embodiment, the second angle range may be less than 160°, and the smaller the angle between the monitor 1 and the support structure 2, the smaller the curvature of the display panel 11, until it changes to a plane. When the display panel 11 is in a plane, it may be set substantially horizontally such that the user may perform operations such as drawing and file processing on the display panel 11. The display panel 11 may receive touch operations.

The curvature of the monitor 1 in the first structural form may be larger than the curvature in the second structural form. As the monitor 1 rotates relative to the support structure 2, when the monitor 1 changes from the first structural form to the second structural form, the curvature of the display panel 11 may gradually decrease until it changes to a plane. When the monitor 1 changes from the second structural form to the first structural form, the curvature of the display panel 11 may gradually increase until it reaches the maximum design curvature.

In one embodiment, when the angle between the monitor 1 and the support structure 2 changes from the first angle range to the second angle range, the drive component 3 may drive the monitor 1 to switch from the first structural form to the second structural form. The curvature in the first structural form may be larger than the curvature in the second structural form. As the monitor 1 rotates relative to the support structure 2, when the monitor 1 switches from the first structural form to the second structural form, the curvature of the display panel 11 may gradually decrease until it changes to a plane. In one embodiment, when the angle between the monitor 1 and the support structure 2 changes from the second angle range to the first angle range, the drive component 3 may drive the monitor 1 to switch from the second structural form to the first structural form. The curvature in the first structural form may be larger than the curvature in the second structural form. As the monitor 1 rotates relative to the support structure 2, when the monitor 1 switches from the second structural form to the first structural form, the curvature of the display panel 11 may gradually increase until it reaches the maximum design curvature.

In the present disclosure, the terms “comprises,” “includes,” or any other variation thereof are intended to cover a non-exclusive inclusion, such that an article or device including a list of elements includes not only those elements, but also other elements not expressly listed. Or it also includes elements inherent to the article or equipment. Without further limitation, an element associated with the statement “comprises a . . . ” does not exclude the presence of other identical elements in an article or device that includes the above-mentioned element.

The disclosed equipment and methods may be implemented in other ways. The apparatus/device embodiments described above are only illustrative. For example, the division of the units is only a logical function division. In actual implementation, there may be other division methods, such as: a plurality of units or components may be combined, or may be integrated into another system, or some features may be ignored, or not implemented. In addition, the coupling, direct coupling, or communication connection between the components shown or discussed may be through some interfaces, and the indirect coupling or communication connection of the devices or units may be electrical, mechanical, or other forms.

The units described above as separate components may or may not be physically separated. The components shown as units may or may not be physical units. They may be located in one place or distributed to a plurality of network units. Some or all of the units may be selected according to actual needs to achieve the purpose of the solution of the present disclosure.

In addition, all functional units in the embodiments of the present disclosure may be integrated into one processing unit, or each unit may be separately used as a unit, or two or more units may be integrated into one unit. The above-mentioned integration units may be implemented in the form of hardware or in the form of hardware plus software functional units.

All or part of the steps to implement the above method embodiments may be completed by hardware related to program instructions. The aforementioned program may be stored in a computer-readable storage medium. When the program is executed, the steps including the above method embodiments may be executed. The aforementioned storage media may include: removable storage devices, read only memories (ROMs), magnetic disks, optical disks or other media that may store program codes.

When the integrated units mentioned above in the present disclosure are implemented in the form of software function modules and sold or used as independent products, they may also be stored in a computer-readable storage medium. Based on this understanding, the technical solutions of the embodiments of the present disclosure in essence or those that contribute to the existing technology may be embodied in the form of software products. The computer software products may be stored in a storage medium and include a number of instructions for instructing the product to perform all or part of the methods described in various embodiments of the present disclosure. The aforementioned storage media may include: random access memory (RAM), read-only memory (ROM), electrical-programmable ROM, electrically erasable programmable ROM, register, hard disk, mobile storage device, CD-ROM, magnetic disks, optical disks, or other media that may store program codes.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the present disclosure. Thus, while the present disclosure has been described in detail with reference to the above described embodiments, the present disclosure is not limited to the above described embodiments, but may be embodied in other equivalent forms without departing from the scope of the present disclosure.

What is claimed is:

1. An electronic apparatus comprising:
a monitor;
a support structure for supporting the monitor; and
a drive component, arranged on a back of the monitor and connected to the support structure, wherein when a relative position relationship between the monitor and the support structure changes, the drive component is configured to change an angle between at least two areas of the monitor and to provide the monitor with at least two different structural forms.

2. The apparatus according to claim 1, wherein:
the monitor includes a display panel and a back shell covering the display panel;
the back shell includes a first shell portion and two second shell portions arranged on opposite sides of the first shell portion;
the drive component is arranged on the back shell;
the electronic apparatus further includes a rotating shaft structure arranged on the first shell portion;
the drive component and the support structure are movably connected through the rotating shaft structure; and
when the relative position relationship between the monitor and the support structure changes, the rotating shaft structure is able to drive the drive component to drive the two second shell portions to rotate relative to the first shell portion, to provide the monitor with different structural forms, wherein a curvature of the monitor is different in the different structural forms.

3. The apparatus according to claim 1, wherein:
the monitor includes a display panel, a back shell covering the display panel, and a back plate arranged on a back of the display panel for supporting the display panel;
the drive component is arranged on the back plate;
the electronic apparatus further includes a rotating shaft structure arranged on the back plate, and the drive component and the support structure are movably connected through the rotating shaft structure;
when the relative position relationship between the monitor and the support structure changes, the rotating shaft structure is able to drive the drive component to drive the two first plates of the back plate to rotate relative to the second plate of the back plate, to provide the monitor with different structural forms; and
the two first plates are arranged on opposite sides of the second plate.

4. The apparatus according to claim 1, wherein:
the monitor includes a display panel, a back shell covering the display panel, and a back plate arranged on a back of the display panel for supporting the display panel;
the drive component is arranged on the back plate;
the electronic apparatus further includes a plate structure between the back plate and the back shell;
the plate structure includes a third plate and two fourth plates arranged on opposite sides of the third plate;
the drive component is arranged on the plate structure, and two opposite edges of the plate structure are connected to the back plate;
a rotating shaft structure is arranged on the third plate, and the drive component and the support structure are movably connected via the rotating shaft structure;
when the relative position relationship between the monitor and the support structure changes, the rotating shaft structure is able to drive the drive component to drive the two fourth plates to rotate relative to the third plate, to drive the back plate to deform, to provide the monitor with different structural forms, wherein a curvature of the monitor is different in the different structural forms.

5. The apparatus according to claim 2, wherein:
the rotating shaft structure includes:
a first shaft;
a shaft seat, used to support the first shaft to rotate; and
a first rotating member, sleeved on the first shaft,
wherein:
the first rotating member is fixedly connected to the support structure and movably connected to the drive component;
when the support structure rotates relative to the monitor, the first rotating member or a driving portion arranged on the first shaft is able to apply a force to the drive component, such that the drive component drives a back panel or the back shell of the monitor to deform and the monitor has at least a curved shape and a flat shape.

6. The apparatus according to claim 5, wherein:
the drive component includes:
a second rotating member sleeved on the first rotating shaft, wherein the second rotating member is movably connected to the first rotating member or the driving portion arranged on the first rotating shaft, and capable of moving in an axial direction of the first rotating shaft under the action of the first rotating member;
a push-pull component movably arranged on the back shell, the back plate or the plate structure of the monitor, wherein the push-pull component is capable of applying a push or pull force to a movable portion of the back shell or the back plate to deform the back shell or the back plate; and
a transmission component connecting the second rotating member and the push-pull component, used for transmitting a force to the push-pull component when the second rotating member moves, to drive the push-pull component to move.

7. The apparatus according to claim 6, wherein:
the transmission component includes a connecting rod and a second rotating shaft arranged on the first shell portion of the back shell, the second plate body of the back plate or the third plate body of the plate body structure;
the connecting rod is able to rotate through the second rotating shaft;
two opposite ends of the connecting rod are respectively connected to the second rotating member and the push-pull component;
when the second rotating member moves in a first direction, the connecting rod is able to rotate counterclockwise and drive the push-pull component to apply a push force to the movable portion of the back shell or the back plate; and
when the second rotating member moves in a second direction, the connecting rod is able to rotate clockwise and drive the push-pull component to apply a pulling force to the movable portion of the back shell or the back plate, wherein the first direction and the second direction are opposite.

8. The apparatus according to claim 7, wherein:
the push-pull component includes:
a transmission member connected to the connecting rod, wherein the transmission member is able to move in the first direction or the second direction under the drive of the connecting rod;
a push-pull rod,
wherein:
two opposite ends of the push-pull rod are respectively and rotatably connected to the movable portion and the main portion of the back shell, the back plate or the plate structure;
the push-pull rod has at least one connecting groove, and a portion of the bottom wall of the at least one connecting groove has a slope;
the transmission member is movably arranged in the at least one connecting groove away from the first end of the connecting rod;
when the second rotating member moves in the first direction, the connecting rod drives the transmission member to move in the second direction, such that the first end of the transmission member slides to the slope, to apply a thrust to the movable portion of the back shell or the back plate through the slope; and
when the second rotating member moves in the second direction, the connecting rod drives the transmission member to move in the first direction, such that the first end of the transmission member slides out of the slope, to apply a pulling force to the movable portion of the back shell or the back plate.

9. The apparatus according to claim 8, wherein:
at least one rotating connecting member is also arranged between the movable portion and the main portion of the back shell, the back plate or the plate structure to support the relative rotation between the movable portion and the main portion.

10. The apparatus according to claim 8, wherein:
two first ends are provided and spaced apart on a side of the transmission member away from the connecting rod, and the two first ends are respectively movably connected to one push-pull rod.

11. The apparatus according to claim 2, wherein:
the rotating shaft structure includes a first rotating shaft structure and a second rotating shaft structure;
the drive component includes a first drive component and a second drive component;
the first rotating shaft structure and the first drive component are arranged in a first area of the back shell, a back plate or a plate structure of the monitor;
the second rotating shaft structure and the second drive component are arranged in a second area of the back shell, the back plate or the plate structure; and
the first area and the second area are symmetrically arranged on two sides of the center line of the back shell, back plate or plate structure.

12. The apparatus according to claim 1, wherein:
a fiber layer is also arranged on the back side of the back shell facing away from the display panel.

13. The apparatus according to claim 1, wherein:
the monitor also includes a backlight control panel for controlling display parameters of the display panel and/or a touch control panel for controlling touch parameters of the display panel;
the backlight control panel is arranged in the main portion of the back shell or back plate of the monitor; and/or
the touch control panel is arranged in the support structure.

14. The apparatus according to claim 1, wherein:
when an angle between the monitor and the support structure is within a first angle range, the monitor is in a first structural form;
when the angle between the monitor and the support structure is within a second angle range, the monitor is in a second structural form;
a curvature of the monitor in the first structural form is larger than the curvature in the second structural form;
when the angle between the monitor and the support structure changes from the first angle range to the second angle range, the drive component is able to drive the monitor to switch from the first structural form to the second structural form.

15. The apparatus according to claim 14, wherein:
when the angle between the monitor and the support structure changes from the second angle range to the first angle range, the drive component is able to drive the monitor to switch from the second structural form to the first structural form.

16. The apparatus according to claim 1, wherein:
the electronic apparatus is placed on a carrier through the support structure.
